(19) United States
(12) Patent Application Publication
(10) Pub. No.: US 2016/0056351 A1
(43) Pub. Date: Feb. 25, 2016

(54) LIGHT-EMITTING DEVICE

(71) Applicant: EPISTAR CORPORATION, Hsinchu (TW)

(72) Inventors: Yu Chih YANG, Taipei (TW); Wu Tsung LO, Taipei (TW)

(21) Appl. No.: 14/466,455

(22) Filed: Aug. 22, 2014

(51) Int. Cl. H01L 33/54; H01L 33/40; H01L 33/44; H01L 33/50; H01L 33/48; H01L 33/58; H01L 33/20; H01L 33/60

(52) U.S. Cl. CPC H01L 33/54; H01L 33/20; H01L 33/405; H01L 33/60; H01L 33/508; H01L 33/486; H01L 33/58; H01L 33/44

(57) ABSTRACT

Disclosed is a light-emitting device. The light-emitting device comprises a light-emitting stack comprising an active layer; a substrate above the active layer, the substrate comprising a first surface and a second surface which is opposite to the first surface and is closer to the active layer than the first surface, wherein the substrate comprises a recess which is circumscribed by a part of the first surface; and a first electrode in the recess. A method for forming the light-emitting device is also disclosed.

### TECHNICAL FIELD

The application relates to a light-emitting device, in particular to a light-emitting device for increasing light emitted from sidewalls of the light-emitting device.

### DESCRIPTION OF BACKGROUND ART

A light-emitting diode (LED) is suitable for diverse lighting applications because of its characteristics of low power consumption, low heat generation, long life, compact, swift response time, and emitting wavelength stability. As shown in FIG. 1, a conventional LED chip comprises a light-emitting stack 130 comprising an n-type semiconductor layer 130a, an active layer 130b, and a p-type semiconductor layer 130c sequentially stacked on the substrate 110 followed by a stacking direction V. Light emitted by the conventional LED chip is extracted mainly from the major light-extracted surface Sm perpendicular to the stacking direction V and is distributed along the vertical direction which is perpendicular to the major light-extracted surface Sm. Less light is extracted from the sidewalls Sw of the LED chip and distributed along the horizontal direction H which is parallel to the major light-extracted surface Sm.

FIG. 2 shows the light intensity distribution of a conventional LED chip. As shown in FIG. 2, most of light is extracted along the axis marked by “0” degree (perpendicular to the major light-extracted surface Sm in FIG. 1) and distributed mainly between the “45” and “−45” degree in the angular coordinate. Less light is extracted from the sidewalls of the LED chip.

### SUMMARY OF THE DISCLOSURE

Disclosed is a light-emitting device. The light-emitting device comprises a light-emitting stack comprising an active layer; a substrate above the active layer, the substrate comprising a first surface and a second surface opposite to the first surface and closer to the active layer than the first surface, wherein the substrate comprises a recess circumscribed by the first surface; and a first electrode in the recess. A method for forming the light-emitting device is also disclosed.

### BRIEF DESCRIPTION OF THE DRAWINGS

FIG. 1 shows a conventional LED chip.

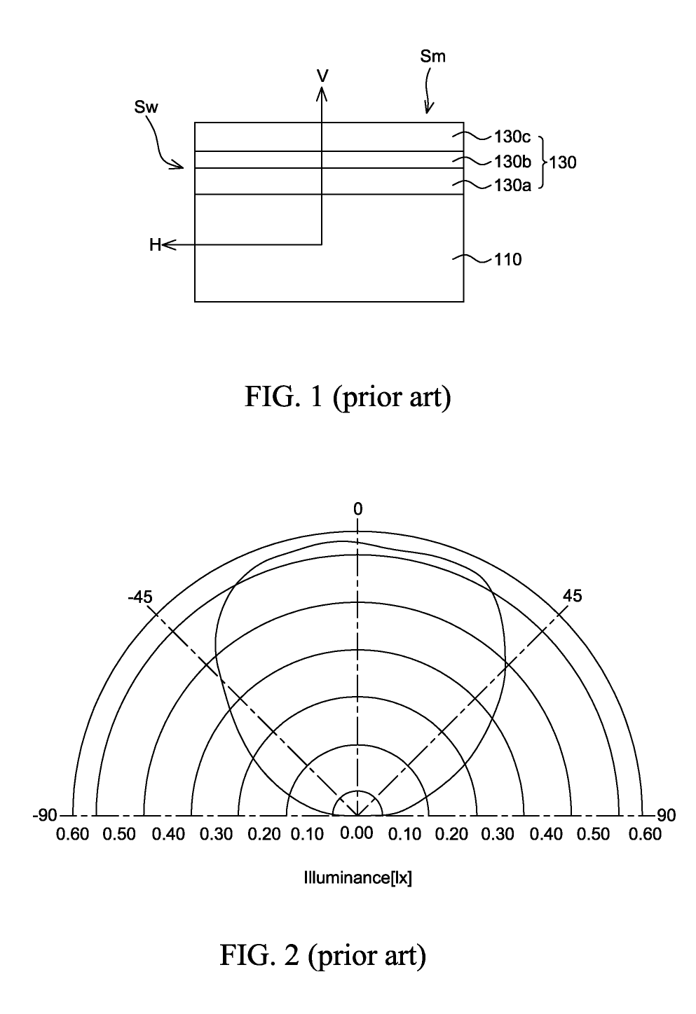

FIG. 2 shows the light intensity distribution of a conventional LED chip.

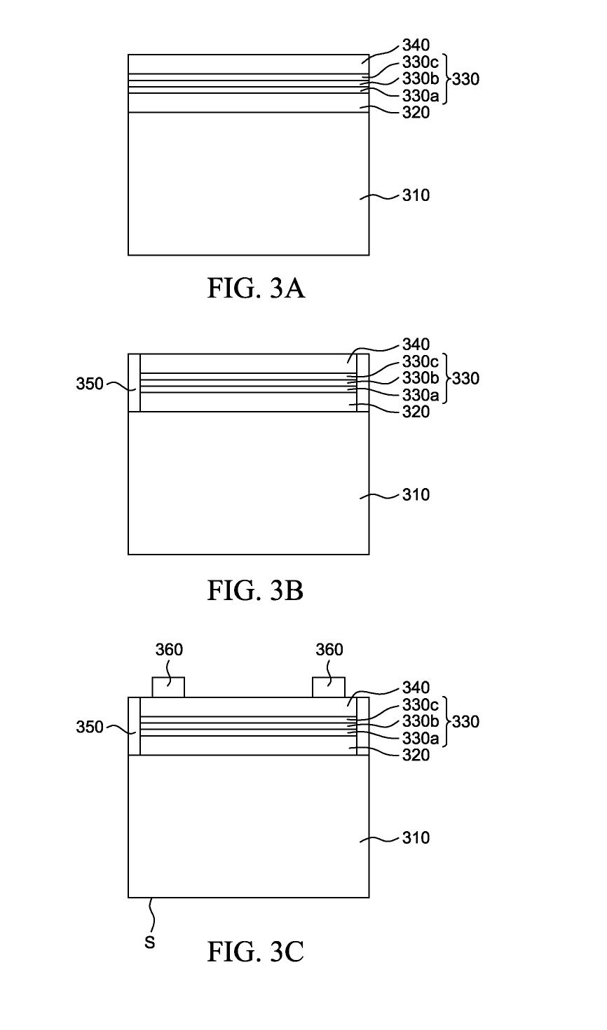

FIGS. 3A to 3G show the method for forming the light-emitting device in accordance with the first embodiment of the present application.

FIGS. 4A and 4B show the light-emitting device in accordance with the second embodiment of the present application.

FIGS. 5A and 5B show the light-emitting device in accordance with the third embodiment of the present application.

FIGS. 6A and 6B show the light-emitting device in accordance with the fourth embodiment of the present application.

FIGS. 7A and 7B show the light-emitting device in accordance with the fifth embodiment of the present application.

FIG. 8 shows the light-emitting device in accordance with the sixth embodiment of the present application.

FIG. 9 shows the light-emitting device in accordance with the seventh embodiment of the present application.

FIG. 10 shows the light-emitting device in accordance with the eighth embodiment of the present application.

### DETAILED DESCRIPTION OF PREFERRED EMBODIMENTS

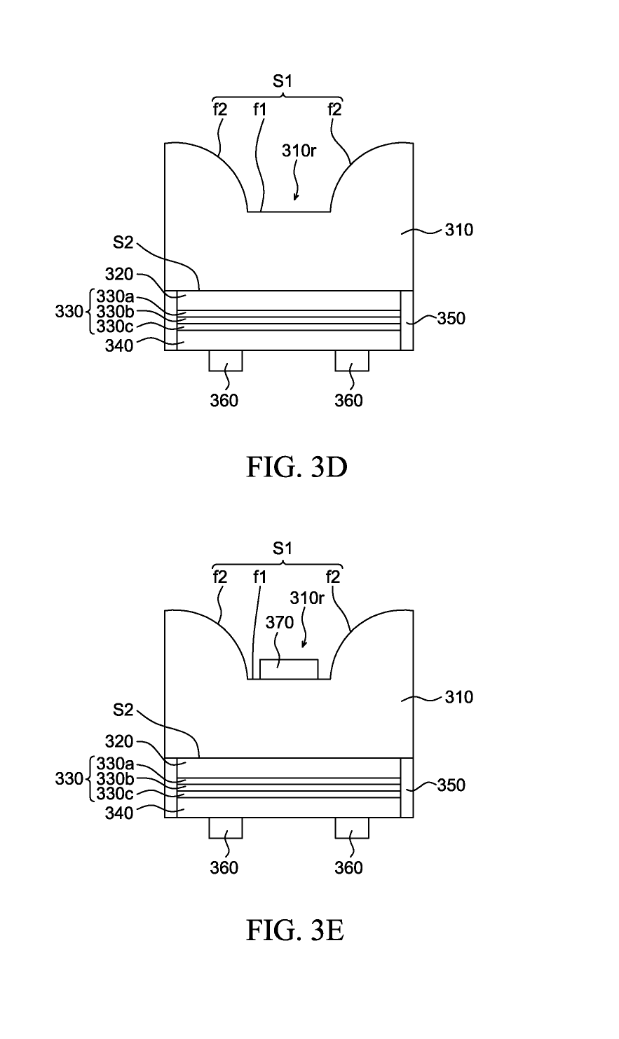

FIGS. 3A to 3G show the method for forming a light-emitting device in accordance with the first embodiment of the present application, wherein FIG. 3G shows a top view of the light-emitting device 300 depicted in FIG. 3F, and FIG. 3F is a cross-sectional view of the light-emitting device 300 along the cross-section line AA′ depicted in FIG. 3G. As shown in FIG. 3A, the method for forming the light-emitting device comprises providing a substrate 310, and epitaxially growing a buffer layer 320 and a light-emitting stack 330 in sequence on the substrate 310. Next, an ohmic contact layer 340 is formed on the light-emitting stack 330 to provide ohmic contact with the light-emitting stack 330. The light-emitting stack 330 is a semiconductor stack comprising a first semiconductor layer 330a with a first conductivity type, an active layer 330b, and a second semiconductor layer 330c with a second conductivity type sequentially epitaxially grown on the buffer layer 320. The first conductivity type and the second conductivity type are of different conductivity types. For example, the first conductivity type is n-type, and the second conductivity type is p-type. When the light-emitting device is driven, the first semiconductor layer 330a and the second semiconductor layer 330c generate carriers (electrons/holes) respectively, and the carriers recombine in the active layer 330b to generate light. The buffer layer 320 and the light-emitting stack 330 comprise group III-V material, for example, AlGaInP series compounds or AlGaInN series compounds.

Next, as shown in FIG. 3B, lithography and etching processes are performed to remove away a part of the buffer layer 320, the light-emitting stack 330, and the ohmic contact layer 340 to expose a portion of the substrate 310. Then a dielectric layer 350 is formed on the sidewalls of the buffer layer 320, the light-emitting stack 330, and the ohmic contact layer 340. The method for forming the dielectric layer 350 comprises deposition or evaporation method. The deposition method comprises PECVD or sputtering, and the evaporation method comprises e-beam method. The material of the dielectric layer 350 comprises an insulating material, such as SiOₓ, SiNₓ, AlOₓ, or AlN. Then, as shown in FIG. 3C, a first electrode 360 is formed on the ohmic contact layer 340 for coupled to an external power source.

The method for forming the light-emitting device further comprises bonding a temporary substrate to the ohmic contact layer 340 and the first electrode 360 by a glue material or a polymer material, such as BCB or epoxy resin. Next, a recess 3100r is formed on the surface S of the substrate 310 by partially etching or sandblasting the substrate 310 as shown in FIG. 3D. In one embodiment, a shape of the recess 310r is formed by adjusting a shape of a photo-resistor layer by lithography process before etching or sandblasting.

As shown in FIG. 3D, the substrate 310 comprises a first surface S1 distant from the active layer 330b and a second surface S2 closer to the active layer 330b than the first surface S1. The recess 310r is circumscribed by the first surface S1 of the substrate 310. In the present embodiment, the first surface S1 comprises a lower portion f1 and an upper portion f2 surrounding the lower portion f1. The lower portion f1 is closer to the active layer 330b than the upper portion f2. The lower portion f1 is substantially a plane and the upper portion f2 comprises a convex having a positive curvature. The upper portion f2 is not parallel to the active layer 330b and corresponding to an area of the first electrode 360 from a top view. In other words, the first electrode 360 is disposed substantially directly under the area corresponding or aligned to the upper portion f2.

As shown in FIG. 3E, the method for forming the light-emitting device further comprises forming a current blocking layer 370 in the recess 310r and on the lower portion f1 of the first surface S1. The current blocking layer 370 comprises an insulating material for blocking an electrical current from flowing therethrough. When viewing from the top as shown in FIG. 3G, the current blocking layer 370 is substantially at a central position of the recess 310r. The upper portion f2 surrounds the current blocking layer 370. Then, as shown in FIG. 3F, a reflective layer 380 is formed at least on the upper portion f2 of the first surface S1, and a second electrode 390 is formed in the recess 310r and directly above the current blocking layer 370. The second electrode 390 conducts an electrical current to the reflective layer 380. The reflective layer 380 has a reflectivity substantially over 80% for light emitted by the active layer 330b and comprises a reflective material, such as Ag, Al or Au, for reflecting light emitted by the active layer 330b as demonstrated by the light path L. The second electrode 390 comprises multiple layers. For example, the second electrode 390 comprises an under layer 390a comprising a diffusion barrier layer 390a2 composed of Pt over an adhesion layer 390a1 composed of Ti and a bonding pad 390b composed of Au over the diffusion barrier layer 390a2. In the present embodiment, the second electrode 390 comprises a same or different material as the material of the reflective layer 380. In one embodiment, the reflective layer 380 and the bonding pad 390b of the second electrode 390 are formed at the same time and have a reflectivity substantially over 80% for light emitted by the active layer 330b. FIG. 3G shows a top view of the light-emitting device 300. A shape of the second electrode 390 and the current blocking layer 370 is a circle from the top view of the light-emitting device 300. In another embodiment, the reflective layer 380 is formed after the bonding pad 390b of the second electrode 390 and comprises a material different from that of the bonding pad 390b. The reflective layer 380 is formed in an area other than the area of the second electrode 390. In order to avoid the possible misalignment between the reflective layer 380 and the bonding pad 390b, the reflective layer 380 slightly covers and overlaps with the bonding pad 390b.

According to the present embodiment, the light-emitting device 300 is provided as in FIGS. 3F and 3G. The light-emitting device 300 comprises the light-emitting stack 330 comprising the first semiconductor layer 330a, the active layer 330b, and the second semiconductor layer 330c. The buffer layer 320 is above the light-emitting stack 330, and the ohmic contact layer 340 is below the light-emitting stack 330. The substrate 310 is above the light-emitting stack 330 and comprises the first surface S1 and the second surface S2 opposite to the first surface S1, wherein the second surface S2 is closer to the active layer 330b than the first surface S1. The substrate 310 comprises the recess 310r which is circumscribed by a part of the first surface S1. The second electrode 390 is in the recess 310r. The first surface S1 comprises the upper portion f2 which is not parallel to the active layer 330b, and the reflective layer 380 is disposed on the upper portion f2. The second electrode 390 is connected with the reflective layer 380 so an electrical current is conducted from the second electrode 390 to the reflective layer 380. The second electrode 390 comprises multiple layers, and one of the layers comprises a material which is the same as the material of the reflective layer 380. The light-emitting device 300 further comprises the current blocking layer 370 under the second electrode 390. The first electrode 360 is disposed below the active layer 330b and substantially directly under the upper portion f2. An electrical current flowing through the second electrode 390) is blocked by the current blocking layer 370 and is spread over the reflective layer 380. Because the first electrode 360 is substantially disposed directly under the upper portion f2 which is not parallel to the active layer 330b, the electrical current is spread to an area of the active layer 330b substantially directly under the upper portion f2. As shown by the light path L in FIG. 3F, light emitted by the active layer 330b is reflected by the reflective layer 380 on the upper portion f2 and then is extracted from the sidewalls of the light-emitting device 300. Furthermore, the dielectric layer 350 on sidewalls of the light-emitting device 300 provides an anti-reflection function for reducing light from being totally internally reflected between the upper and lower surfaces of the light-emitting device 300. The dielectric layer 350 has a refractive index smaller than the refractive indices of the buffer layer 320, the light-emitting stack 330, and the ohmic contact layer 340. The refractive index of the dielectric layer 350 is larger than that of the encapsulating material for packaging the light-emitting device 300 and/or that of the air. Therefore the refractive indices of the light-emitting stack 330, the dielectric layer 350, and the encapsulating material are gradually decreased to facilitate light to be extracted from the sidewalls.

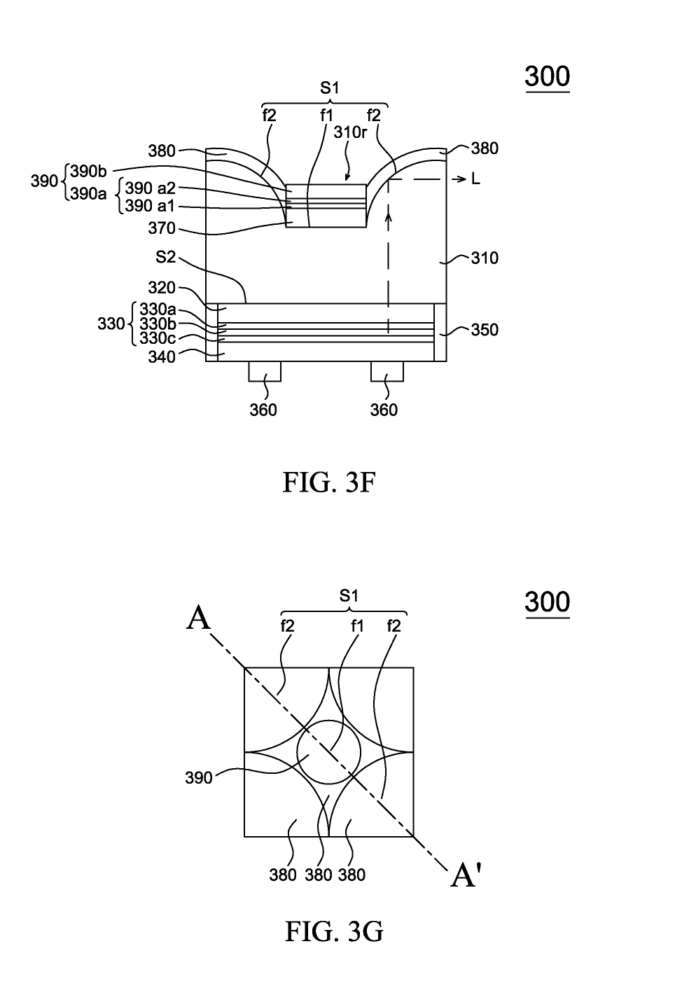

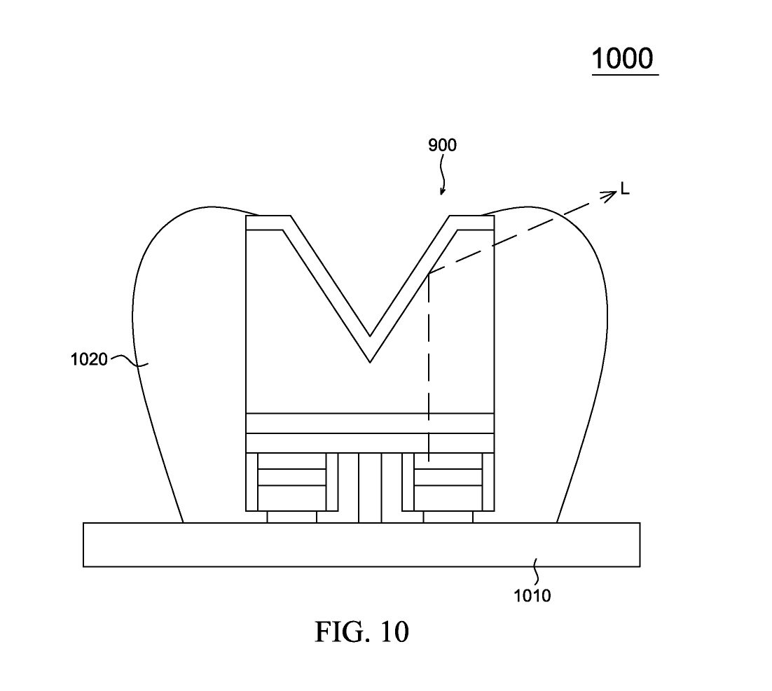

FIGS. 4A and 4B show the light-emitting device in accordance with the second embodiment of the present application, wherein FIG. 4B shows a top view of the light-emitting device 400 depicted in FIG. 4A, and FIG. 4A is a cross-sectional view of the light-emitting device 400 along the cross-section line BB′ depicted in FIG. 4B. The present embodiment shows a recess having a different profile from that of the first embodiment. The present embodiment shows the recess 410r having a cross-sectional shape of trapezoid. The first surface S1 comprises a lower portion f1, an upper portion f2, and a peripheral portion p1. The peripheral portion is outer than the upper portion f2 and not recessed. The peripheral portion p1 is used to control the light field angle of light extracted from the light-emitting device 400. Besides, the peripheral portion p1 provides a plane for facilitating the coating of a phosphor (as illustrated later in FIG. 10) such that some of the phosphor 1020 can be disposed on the peripheral portion p1 and better Color Over Angle (COA) of the light-emitting device is achieved. The lower portion f1 is closer to the active layer 430b than the upper portion f2. The lower portion f1 is substantially a plane which connects the upper portion f2, and the upper portion f2 comprises substantially four slopes surrounding the lower portion f1. The second electrode 490 is disposed on the lower portion f1. An electrical current is spread toward the upper portion f2 which effectively direct light toward and outside the sidewalls of the light-emitting device 400. The upper portion f2 is not parallel to the active layer 430 band is corresponding to the first electrode 460. In other words, the first electrode 460 is disposed substantially directly under the upper portion f2 and is corresponding or aligned to the upper portion f2. Besides, in the present embodiment, the under layer 490a of the second electrode 490 comprises the same material as that of the reflective layer 480. Both the under layer 490a of the second electrode 490 and the reflective layer 480 comprise Ag and are formed at the same time in the present embodiment. The bonding pad 490b of the second electrode 490 comprises Au. Further, the dielectric layer 450 is not only formed on sidewalls of the buffer layer 420, the light-emitting stack 430, and the ohmic contact layer 440, but also formed on part of the surface of the ohmic contact layer 440 for preventing the ohmic contact layer 440 from being electrically contacted with an solder material of an submount when the first electrode 460 is soldered or bonded to the solder material of the submount. The light-emitting device 400 is substantially the same as the light-emitting device 300 shown in FIGS. 3F and 3G except for those illustrated above. The element corresponding to the same or similar element in FIGS. 3F and 3G is labeled with the same last two digits of the corresponding reference character but changing the first digit from “3” to “4”. For example, the substrate 410 in FIGS. 4A and 4B has the same or similar material and structure, and performs the same or similar function to the substrate 310 in FIGS. 3F and 3G.

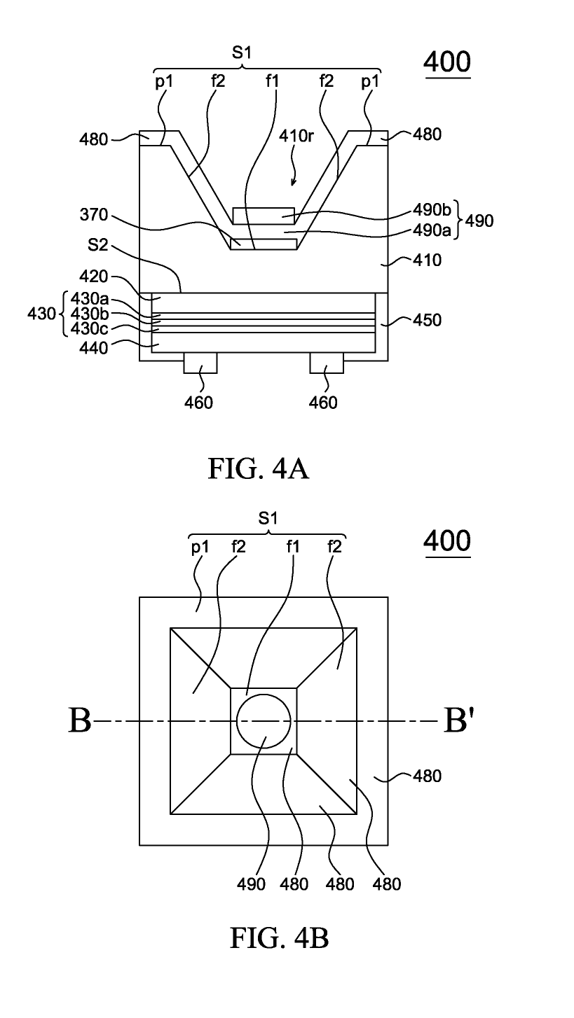

FIGS. 5A and 5B show the light-emitting device in accordance with the third embodiment of the present application, wherein FIG. 5A shows a top view of the light-emitting device 500 depicted in FIG. 5B, and FIG. 5B is a cross-sectional view of the light-emitting device 500 along the cross-section line CC′ depicted in FIG. 5A. The present embodiment shows the recess 510r having a cross-sectional shape of a wing shape. The first surface S1 comprises a lower portion f1, an upper portion f2, and the area a1 which is not recessed. The lower portion f1 is closer to the active layer 530b than the upper portion f2. The lower portion f1 is substantially a line which connects two parts of the upper portion f2, and each of parts of the upper portion f2 is a convex having a positive curvature. The upper portion f2 is not parallel to the active layer 530b. It is noted that the upper portion f2 is corresponding to the first electrode 560. In other words, the first electrode 560 is disposed substantially directly under the upper portion f2 and is corresponding or aligned to the upper portion f2. In addition, as shown in FIG. 5A, the second electrode 590 is disposed in the area a1, while the recess 510r is formed in the rest area. That is, the second electrode 590 is disposed at one end of the first surface S1 when viewed from the top. The second electrode 590 is connected with the reflective layer 580 through the reflective layer 580 formed on the sidewall sw′ of the recess 510r (indicated by the dashed line near the interface of the upper portion f2 and the area a1 in FIG. 5A). As illustrated in the first embodiment, the second electrode 590 comprises a plurality of layers, and the topmost layer (i.e., as the bonding pad 390b in FIG. 3F in the first embodiment) and the reflective layer 580 is formed at the same time. In the present embodiment, both the topmost layer of the second electrode 590 and the reflective layer 580 comprise Au and are formed at the same time. An electrical current is conducted from the second electrode 590 which is disposed at one end of the first surface S1 to the reflective layer 580. Further, the dielectric layer 550 is not only formed on sidewalls of the buffer layer 520, the light-emitting stack 530, and the ohmic contact layer 540, but also formed on part of the surface of the ohmic contact layer 540. The light-emitting device 500 is substantially the same as the light-emitting device 300 shown in FIGS. 3F and 3G, except for those illustrated above. The element corresponding to the same or similar element in the first embodiment is labeled with the same reference character except that the first digit is changed from “3” to “5”. For example, the substrate 510 in FIGS. 5A and 5B has the same or similar material and structure, and performs the same or similar function to the substrate 310 in FIGS. 3F and 3G.

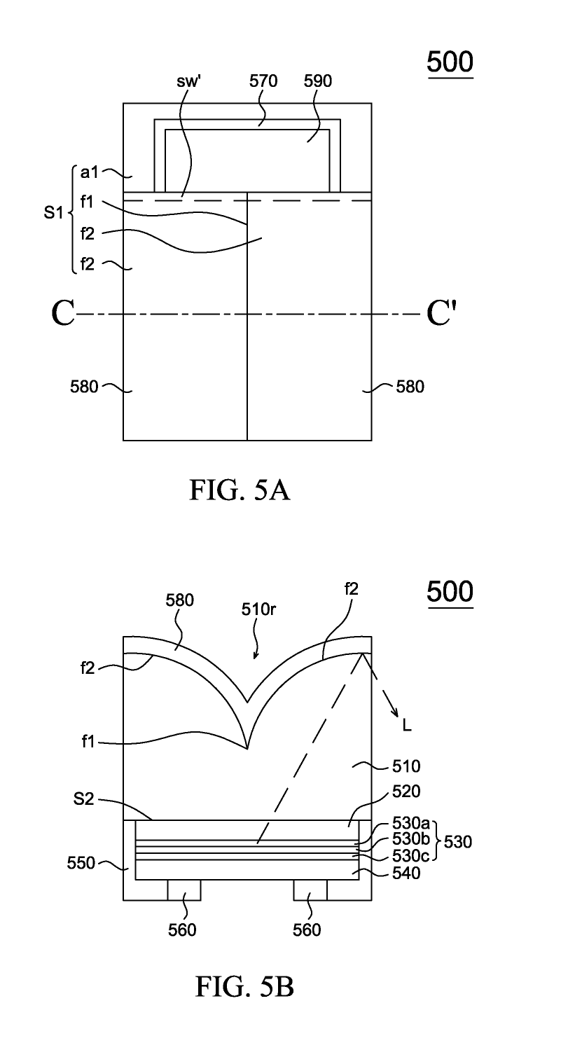

FIGS. 6A and 6B show the light-emitting device in accordance with the fourth embodiment of the present application, wherein FIG. 6A shows a top view of the light-emitting device 600 depicted in FIG. 6B, and FIG. 6B is a cross-sectional view of the light-emitting device 600 along the cross-section line DD′ depicted in FIG. 6A. The present embodiment shows the recess 610r having a cross-sectional shape of a V-shape. The first surface S1 comprises a lower portion f1, an upper portion f2, the peripheral portion p1 and the area a1. The peripheral portion p1 and the area a1 are areas which are not recessed in the present embodiment. The lower portion f1 is closer to the active layer 630b than the upper portion f2. The lower portion f1 is substantially a line which connects two parts of the upper portion f2, and each of parts of the upper portion f2 is substantially a plane. The upper portion f2 is not parallel to the active layer 630b. It is noted that the upper portion f2 is corresponding to the first electrode 660. In other words, the first electrode 660 is disposed substantially directly under the upper portion f2 and is corresponding or aligned to the upper portion f2. The light-emitting device 600 is substantially the same as the light-emitting device 500 shown in FIGS. 5A and 5B, except for those illustrated above. The element corresponding to the same or similar element in the FIGS. 5A and 5B is labeled with the same reference character except that the first digit is changed from “5” to “6”. For example, the substrate 610 in FIGS. 6A and 6B has the same or similar material and structure, and performs the same or similar function to the substrate 510 in FIGS. 5A and 5B.

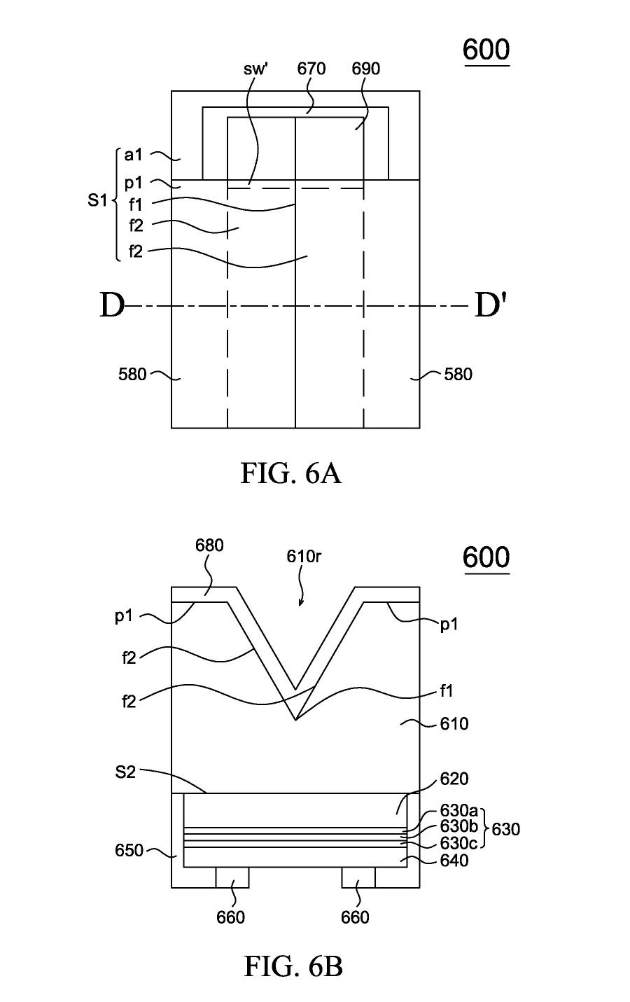

FIGS. 7A and 7B show the light-emitting device in accordance with the fifth embodiment of the present application, wherein FIG. 7A shows a top view the light-emitting device 700 depicted in FIG. 7B, and FIG. 7B is a cross-sectional view of the light-emitting device 700 along the cross-section line EE′ depicted in FIG. 7A. The present embodiment shows the recess 710r having a cross-sectional shape of a U-shape. The first surface S1 comprises a lower portion f1, the upper portion f2, and the area a1 which is not recessed in the present embodiment. The lower portion f1 is closer to the active layer 730b than the upper portion f2. The lower portion f1 is substantially a line which connects two parts of the upper portion f2, and each of parts of the upper portion f2 is a concave having a negative curvature. Compared with the light-emitting device 500 in FIGS. 5A and 5B which the upper portion f2 comprises the convex having a positive curvature, the concave having a negative curvature for the upper portion f2 in the present embodiment provides the light-emitting device 700 a wider light extraction angle. To be more specific, light reflected at a position near the sidewall of the substrate 710 is more toward the vertical direction because of the concave having a negative curvature for the upper portion f2 as shown by the light path marked by L in FIG. 7B. Therefore the light-emitting device 700 has a wider light extraction angle than the light-emitting device 500. The upper portion f2 is not parallel to the active layer 730b. It is noted that the upper portion f2 is corresponding to the first electrode 760. In other words, the first electrode 760 is disposed substantially directly under the upper portion f2 and is corresponding or aligned to the upper portion f2. In addition, unlike the aforementioned embodiments, the reflective layer 780 does not cover the whole recess 710r in the present embodiment. As shown in FIGS. 7A and 7B, the reflective layer 780 is substantially a finger. It is noted that even though the reflective layer 780 does not cover the whole recess 710r, the light-emitting device 700 still has a good efficiency to provide side-emitting light because the difference of the refractive indices of the substrate 710 and the ambient air, as well as the U-shape cross-section provides a TIR (Totally Internal Reflection) for light emitted by the active layer 730b. The light-emitting device 700 is substantially the same as the light-emitting device 500 shown in FIGS. 5A and 5B, except for those illustrated above. The element corresponding to the same or similar element in the FIGS. 5A and 5B is labeled with the same reference character except that the first digit is changed from “5” to “7”. For example, the substrate 710 in FIGS. 7A and 7B has the same or similar material and structure, and performs the same or similar function to the substrate 510 in FIGS. 5A and 5B.

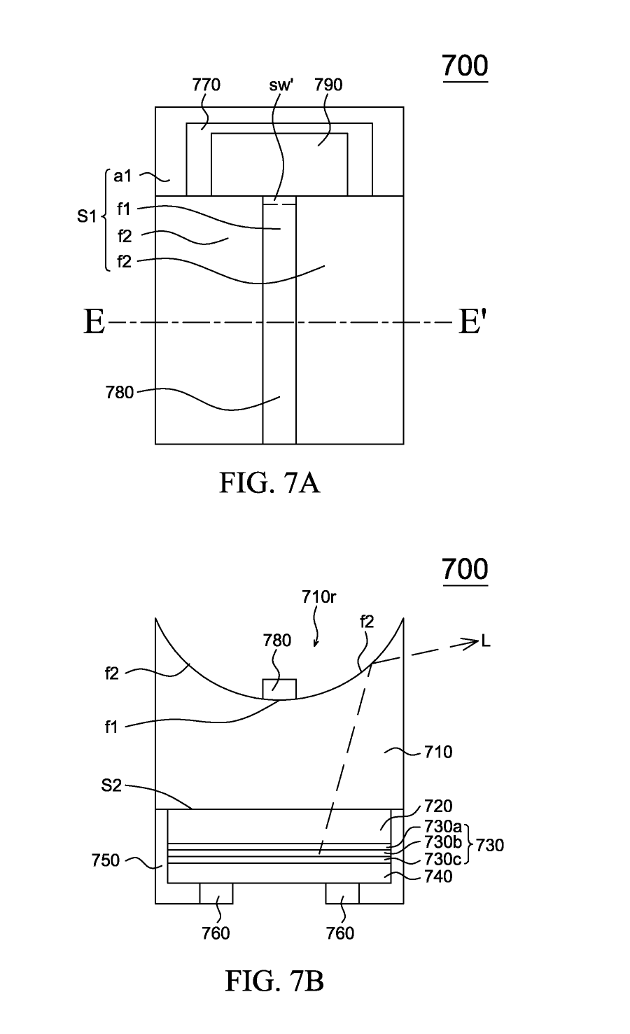

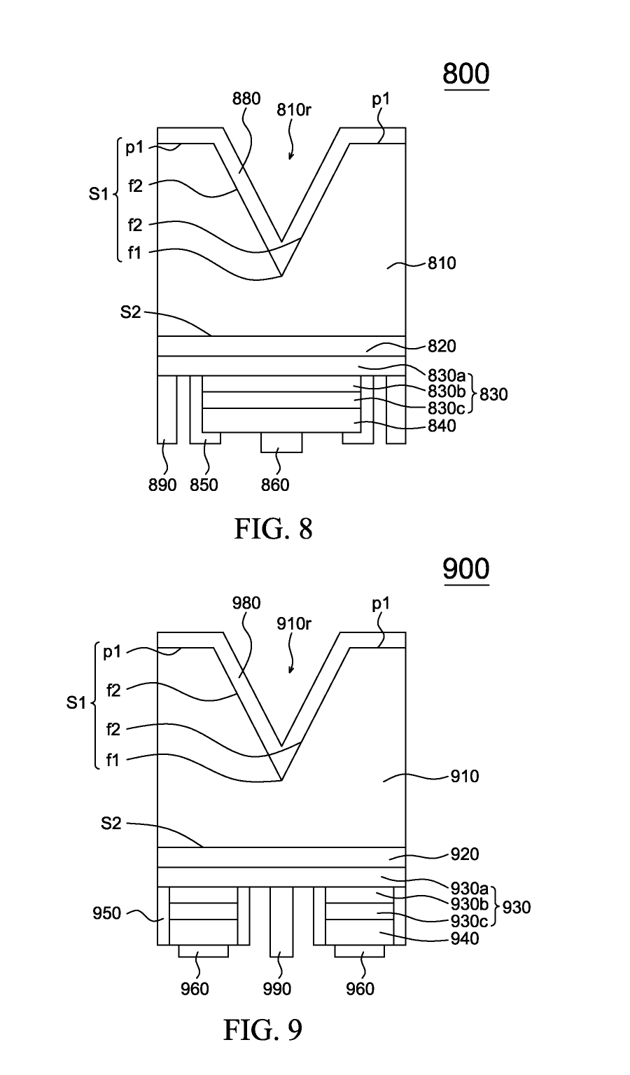

In the aforementioned embodiments, the substrates 310-710 are electrical conductive substrates. In other words, the aforementioned embodiments are vertical type light-emitting devices for having the first and second electrodes respectively disposed on opposite sides of the substrate in each of light-emitting devices. FIGS. 8 and 9 show the light-emitting devices in accordance with the sixth and seventh embodiments of the present application, respectively. Both FIGS. 8 and 9 show horizontal type light-emitting devices for having the first and second electrodes disposed on the same side of substrate in each of the light-emitting devices. The substrates 810 and 910 are electrical non-conductive substrates, for example, sapphire or MN substrates. Unlike the second electrode 390 in FIGS. 3F and 3G which is disposed over the substrate 310 and connected with the reflective layer 380, since the substrates 810 and 910 are electrical non-conductive substrates, the second electrode 890 in FIG. 8 and the second electrode 990 in FIG. 9, which both are corresponding to the second electrode 390, are disposed below the substrate and connected directly with the first semiconductor layers 830a and 930a, respectively. Accordingly, a current blocking layer like the current blocking layer 370 in FIGS. 3F and 3G is not used in both FIGS. 8 and 9. In addition, the light-emitting stack 930 is split into two stacks in FIG. 9. The light-emitting devices 800 and 900 in FIGS. 8 and 9 are substantially the same as the light-emitting device 300 shown in FIGS. 3D and 3G, except for those illustrated above. The element corresponding to the same or similar element in FIGS. 3F and 3G is labeled with the same reference character except that the first digit is changed from “3” to “8” and “9” for FIGS. 8 and 9, respectively. For example, the substrates 810 and 910 in FIGS. 8 and 9 have the same or similar material and structure, and perform the same or similar function to the substrate 310 in FIGS. 3F and 3G.

FIG. 10 shows the light-emitting devices in accordance with the eighth embodiment of the present application. It is noted that while the light-emitting device 900 in FIG. 9 is used as an example for illustration, other light-emitting devices in the aforementioned embodiments can be applied to this embodiment. In the present embodiment, the light-emitting device 900 is mounted to a sub-mount 1010. A phosphor 1020 covers the sidewalls of light-emitting stack and the substrate. As illustrated by the light path marked by L, light is emitted by the light-emitting device 900 and further converted by the phosphor 1020. For example, the light-emitting device 900 emits blue light, the phosphor 1020 comprises a YAG phosphor, and white light is provided by the light-emitting device 1000 in the present embodiment.

The above-mentioned embodiments are only examples to illustrate the theory of the present invention and its effect, rather than be used to limit the present invention. Other alternatives and modifications can be made by a person of ordinary skill in the art of the present application without departing from the spirit and scope of the application, and are within the scope of the present application.

What is claimed is:

1. A light-emitting device comprising:
a light-emitting stack comprising an active layer;
a substrate above the active layer, the substrate comprising a first surface and a second surface which is opposite to the first surface and is closer to the active layer than the first surface, wherein the substrate comprises a recess which is circumscribed by a part of the first surface; and
a first electrode in the recess.

2. The light-emitting device as claimed in claim 1, wherein the first surface comprises an upper portion which is not parallel to the active layer.

3. The light-emitting device as claimed in claim 2, further comprising a reflective layer on the upper portion.

4. The light-emitting device as claimed in claim 3, wherein the first electrode is connected with the reflective layer.

5. The light-emitting device as claimed in claim 3, wherein the first electrode comprises multiple layers, and one of the layers comprises a material which is the same as the material of the reflective layer.

6. The light-emitting device as claimed in claim 1, wherein the recess substantially has a cross section of V-shape, U-shape, trapezoid, wing-shape, or wing-shape with a flat part connecting two wings.

7. The light-emitting device as claimed in claim 1, further comprising a current blocking layer under the first electrode.

8. The light-emitting device as claimed in claim 1, further comprising a dielectric layer on sidewalls of the light-emitting stack.

9. The light-emitting device as claimed in claim 2, further comprising a second electrode below the active layer and substantially directly under the upper portion.

10. The light-emitting device as claimed in claim 1, wherein the first surface comprises a lower portion and an upper portion, and the lower portion is closer to the active layer than the upper portion.

11. The light-emitting device as claimed in claim 10, wherein the lower portion comprises a plane or a line, and the upper portion comprises a plane, a concave, or a convex.

12. The light-emitting device as claimed in claim 10, wherein the upper portion is not parallel to the active layer.

13. The light-emitting device as claimed in claim 1, wherein light emitted from the active layer is substantially extracted from sidewalls of the light-emitting stack or sidewalls of the substrate.

14. The light-emitting device as claimed in claim 10, wherein the first surface further comprises a peripheral portion which does not circumscribe the recess.

15. The light-emitting device as claimed in claim 1, further comprising a phosphor covering sidewalls of the light-emitting stack and sidewalls of the substrate.

16. A light-emitting device comprising:
a light-emitting stack comprising an active layer;
a substrate above the active layer, the substrate comprising a first surface and a second surface which is opposite to the first surface and is closer to the active layer than the first surface, wherein the substrate comprises a recess which is circumscribed by a part of the first surface, and the first surface comprises an upper portion which is not parallel to the active layer;
a reflective layer on the upper portion;
a first electrode below the substrate; and
a second electrode below the substrate.

17. The light-emitting device as claimed in claim 16, wherein light emitted from the active layer is substantially extracted from sidewalls of the light-emitting stack or sidewalls of the substrate.

18. The light-emitting device as claimed in claim 16, further comprising a dielectric layer on sidewalls of the light-emitting stack.

19. The light-emitting device as claimed in claim 16, further comprising a sub-mount below the active layer.

20. The light-emitting device as claimed in claim 16, further comprising a phosphor covering sidewalls of the light-emitting stack and sidewalls of the substrate.
